(19) United States
(12) Patent Application Publication
(10) Pub. No.: US 2017/0152970 A1
(43) Pub. Date: Jun. 1, 2017

(54) CONSUMABLE INTERFACE PLATE FOR TOOL INSTALL

(71) Applicant: Intel Corporation, Santa Clara, CA (US)

(72) Inventor: Roopinderjit S. BATH, Hillsboro, OR (US)

(21) Appl. No.: 15/325,703

(22) PCT Filed: Dec. 19, 2014
(86) PCT No.: PCT/US2014/071721

§ 371 Date: Jan. 11, 2017

Related U.S. Application Data
(60) Provisional application No. 62/039,382, filed on Aug. 19, 2014.

(51) Int. Cl. F16L 5/00; H01L 21/67

(52) U.S. Cl. CPC F16L 5/00; H01L 21/67017

(57) ABSTRACT

An apparatus including an interface operable to be connected to a pedestal or a raised floor for an integrated circuit tool, the interface containing a plurality of openings for utility connections on an input side and on an output side of the interface. An apparatus including an interface operable to be connected to a pedestal or a raised floor and containing a plurality of openings for utility connections on an input side and on an output side of the interface; connectors connected through respective openings in the interface, the connectors operable for connection to a respective utility; and a tool coupled to respective ones of the connectors. A method including coupling one or more utilities from a source to an input side of an interface coupled to a pedestal; and coupling a tool to the one or more utilities at an output side of the interface.

### CROSS-REFERENCE TO RELATED APPLICATION

This application claims the benefit of the earlier filing date of co-pending U.S. Provisional Patent Application No. 62/039,382, filed Aug. 19, 2014 and incorporated herein by reference.

### BACKGROUND

Field

Tool install.

Description of Related Art

Various integrated circuit chip process and packaging environments use a number of different tools. In chip manufacturing, for example, representative tools include etching tools, lithography tools and deposition tools. Each of these tools requires various utilities such as water, gas(es), vacuum, liquid chemicals, etc. These utilities are typically brought to the tool after the tool is placed in the factory (e.g., after the tool is installed on a pedestal). Thus, once the tool is installed, technicians (trades) must connect such tool to utilities. Such tool install design tends to take a considerable amount of time.

### BRIEF DESCRIPTION OF THE DRAWINGS

FIG. 1 shows a cross-sectional side view of an embodiment of a tool on a pedestal, the tool having a number of utilities that are connected to an interface plate connected to the pedestal.

FIG. 2 shows a top plan view of the pedestal of FIG. 1 including the interface plate.

FIG. 3 shows another embodiment of an assembly including a pedestal having an interface vessel connected thereto wherein the interface plate may be used to connect utilities between the factory (source) to one or more tools.

FIG. 4 shows a top view of the pedestal of FIG. 3 including the interface vessel.

FIG. 5 shows a cross-sectional side view of another embodiment of an assembly of a pedestal including an interface vessel connected thereto.

FIG. 6 is a top plan view of the pedestal and interface of FIG. 5.

FIG. 7 shows a top side perspective view of another embodiment of an interface vessel.

FIG. 8 shows a top side perspective view of a portion of a raised floor having an interface connected to legs of the raised floor.

### DETAILED DESCRIPTION

An interface is described that, in one aspect, will interface between one or more factory utilities and a tool. Representative configurations for an interface include a plate or vessel to which one or more utilities may be connected from a source (input) in, for example, a chip manufacturing factory or facility and to which output lines may be connected wherein such output lines may be connected to one or more tools. The interface increases a velocity of tool installation by trades and minimizes the need to reinstall their work for tool move-ins. The interface can also be used to manifold common utilities together outside of a tool without changing a tool design/configuration. The interface can further be used to facilitate scope for future conversions ahead of time by, for example, plumbing extra utility lines to the interface in anticipation of future modifications (e.g., improvements, changes) to a tool (e.g., future converts in place).

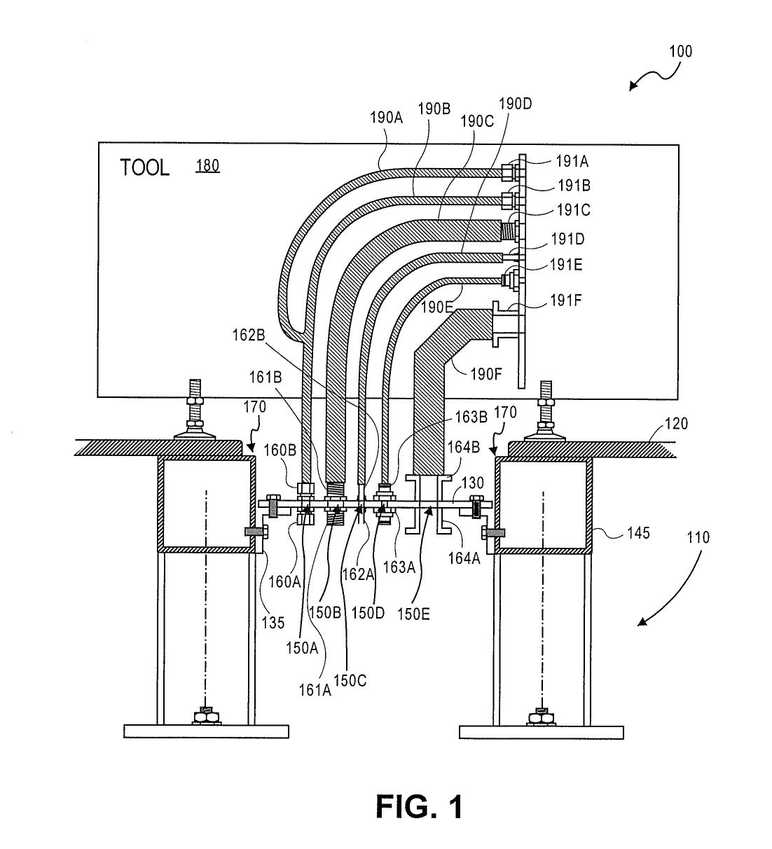

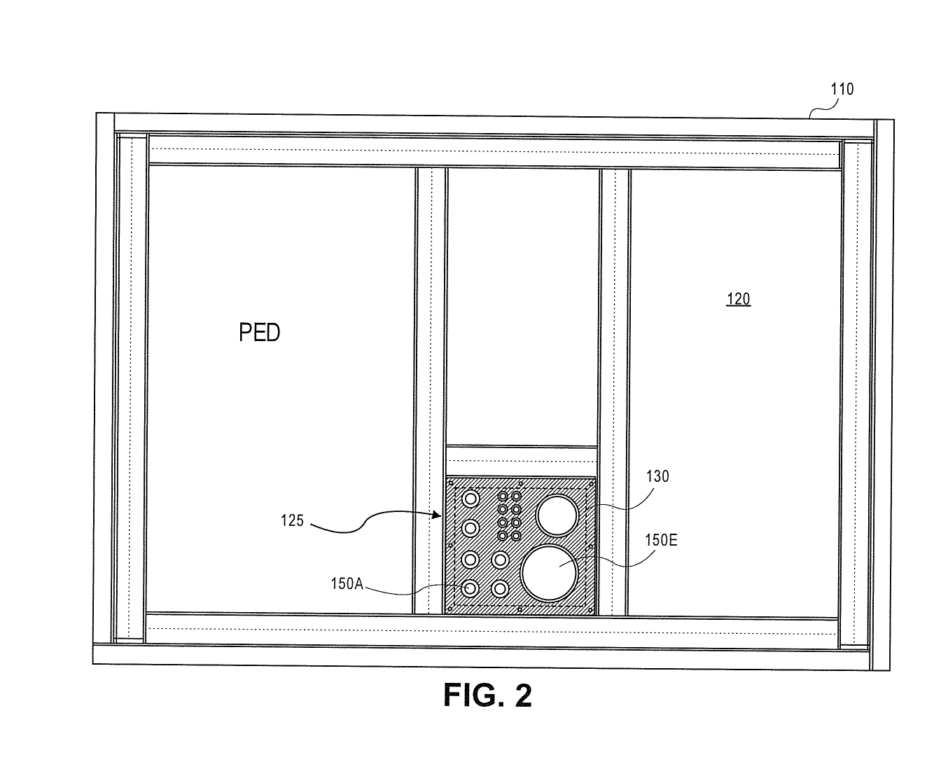

FIG. 1 shows a cross-sectional side view of an embodiment of a tool on a pedestal, the tool having a number of utilities that are connected to an interface (an interface plate) on the table. FIG. 2 shows a top plan view of the pedestal of FIG. 1 including the interface plate. Referring to FIG. 1 and FIG. 2, in one embodiment, pedestal 110 of assembly 100 (pedestal plus interface plate plus tool) has a rectangular shape with a generally planar surface. Any limitation on the length and width of a pedestal, in one embodiment, would be determined based on a size of a tool or possible tools to be positioned on the pedestal. In one embodiment, pedestal 110 includes a planar, horizontal surface plate 120 operable to support a tool or tools. Surface plate 120 includes cut out 125 that defines an area for interface plate 130 to be positioned therein. FIG. 1 shows interface plate 130 fastened to pedestal 110 by, for example, L brackets 135 that connect interface plate 130 to pedestal legs 140 and at a position that is below the plane of surface plate 120 of pedestal 110 (below the plane as viewed) in FIG. 1.

In one embodiment, interface plate 130 may be made of a material similar to a material used to fabricate surface plate 120 or another material, such as a chemically inert material. A representative material includes stainless steel. Interface plate 130 has a number of openings to allow for various types and sizes of connections. Representative of such openings are opening 150A and opening 150E illustrated in FIG. 2 having different sizes (different diameters) that will, in one aspect, depend on the utility being connected to interface plate 130. FIG. 1 shows a number of different connectors connected to interface plate 130 (through respective openings in interface plate 30). Such connectors can include a number of different types representatively selected by the utility being brought to the interface plate. Representative types include:

Water: threaded compression, quick disconnects, ORFS fittings/unions, barbs, unions, flanges, flare-type;

Exhaust: collars, tube/pipe stubs, flange type connections;

Drain: socket, flanged, threaded, compression;

Gases: metal gaskets fittings (VCR, UJR, etc.), compression, threaded, bulkhead bored through fittings, push-type fittings;

Vacuum: vacuum flanges, push-type fittings;

Chemicals: flare-type fittings, pillar-type fittings, flanged, bulkhead fittings for double containment; and

Electrical: jacks, connectors (for connecting main power feeders, low voltage control signaling, raceway/cable tray bonding, grounding, EMI, etc.).

In one embodiment, similar connectors are connected on opposite sides of interface plate 130. FIG. 1 shows, representatively, fitting 160A and fitting 160B of the compression type connected through opening 150A of interface plate 130; connector 161A and connector 161B of the male national pipe thread (MNPT) type connected through opening 150B; connector 161A and connector 161B of the tube stub connected through opening 150B of interface plate 130; connector 162A and connector 162B connected through opening 150C of interface plate 130; connector 163A and connector 163B of the push fitting type connected through opening 150D of interface plate 130; and connector 164A and connector 164B of the flange type connected on opposite sides of interface plate 130 through opening 150E in the plate.

In one embodiment, interface plate 130 is fabricated before tool arrival at its destination in the factory or end use facility. Interface plate 130 is connected to pedestal 110 prior to tool arrival allowing the trades to connect various utilities to the fittings on the factory or source side (e.g., connections to connectors 160A, 161A, 162A, 163A and 164A) prior to installing a tool on pedestal 110. Because interface plate 130 is disposed beneath a plane of surface plate 120 of pedestal 110 (below the plane as viewed), such interface plate may be covered by a solid cover plate (not shown) until access to interface plate 130 is desired from a tool side. FIG. 1 shows shelf 170 between surface plate 120 and bracket 145 connected to a pedestal leg (pedestal leg 140). Such shelf provides an area to accommodate a cover plate thereon.

The embodiment shown in FIG. 1 may be used to connect a number of different utilities to interface plate 130. Once tool 180 is disposed on surface plate 120 of pedestal 110, the needed utilities for the operation of such tool may be connected to the tool. FIG. 1 shows utility lines (e.g., tubes) 190A, 190B, 190C, 190D, 190E and 190F connected through connectors to tool 180. Each of lines 190A-190F includes a corresponding connector 191A, 191B, 191C, 191D, 191E and 191F for connecting to connections on tool 180 (e.g., to mate with connections on tool 180). In one embodiment, lines 190A-190F are individually selected for a type of material that will flow through such lines. A representative material for lines 190A-190F for utilities of a relatively inert material is stainless steel. In one embodiment, the respective lines run from interface plate 130 to connections of tool 180 have generally the same length and size regardless of the tool or where a tool is in a factory.

FIG. 1 shows an embodiment where multiple lines may be manifolded into different connections between tool 180 and interface plate 130. Specifically, FIG. 1 shows a line extending from connector 160B towards multiple connectors on tool 180 through connector 190A and connector 190B. As illustrated, a single line is connected to interface plate 130 and the line is changed to lines 190A and 190B for connection to connector on tool 180.

As illustrated with the number of lines in FIG. 1, in one embodiment, a tool may not require every utility provided to interface plate 130. One advantage of having the ability to run different utilities to interface plate 130 is that future modifications or improvements to a tool can be accommodated without significant re-working of utility lines. In an example where additional process gas utility might be added to a tool to allow for additional or improved processing by the tool (a next generation of a tool), the manufacturer of the tool may be consulted as to where a connection for such additional utility might be placed on a tool, so that interface plate 130 can be manufactured with such next generation in mind.

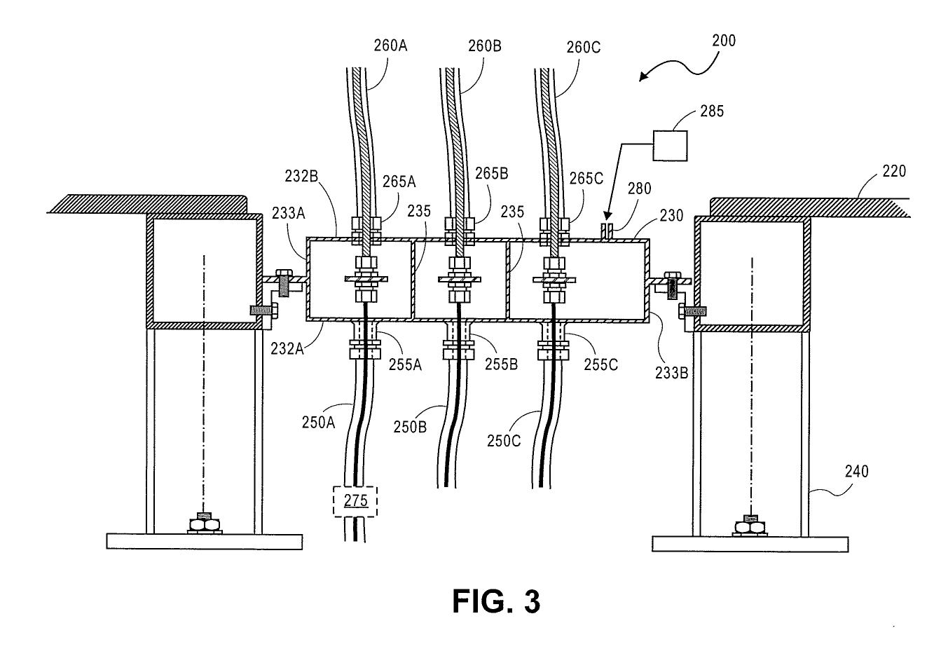

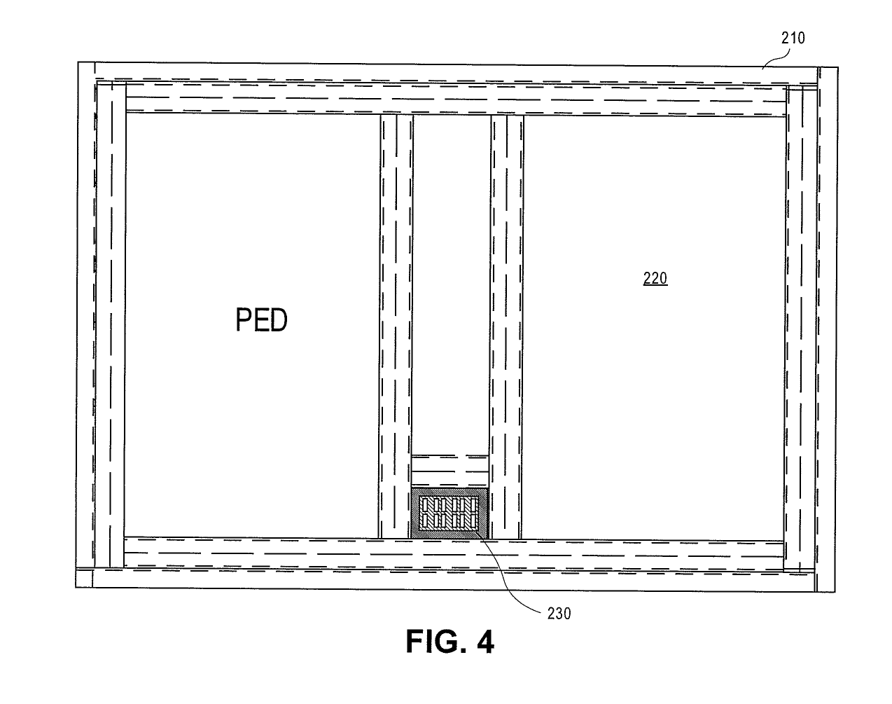

FIG. 3 shows a cross-section side view of another embodiment of an assembly including a pedestal having an interface connected therein, where the interface plate may be used to (is operable to) connect utilities between the factory (source or input) to one or more tools (output). FIG. 4 shows a top view of the pedestal of FIG. 3 including the interface therein. In the embodiment described with reference to FIGS. 3 and 4, the interface may be used with utilities that are toxic and/or flammable. Generally, in the microprocessor manufacturing industry, utilities that are toxic and/or flammable are often run in double contained lines. Such lines include a primary line to carry the utility (e.g., chemical or gas) and a secondary line that surrounds such primary line. Ideally, there is a desire not to have any breaks in the double contained lines as it is difficult to install a secondary fitting around a mechanical fitting that serves in the break.

Referring to FIG. 3 and FIG. 4, assembly 200 includes pedestal 210 including surface plate 220 having an opening therein and an interface of interface vessel 230 disposed in the opening and connected to legs 240 of pedestal 210. In one embodiment, interface vessel 230 is a vessel having a body of, for example, stainless steel, that defines a volume therein. FIG. 3 shows interface vessel 230 including opposing side portions 232A and 232B and opposing side portions 233A and 233B. The opposing side portions define volume 234 within interface vessel 230. Disposed within interface vessel 230 are connectors for a primary line of double-contained lines. FIG. 3 shows double-contained lines 250A, 250B and 250C from the factory or facility (source or input). FIG. 3 also shows double-contained lines 260A, 260B and 260C connected on a tool side of interface vessel 230 (output side). Such output connector lines are double-contained lines that are operable to be connected to a tool through suitable connectors on an end of the lines (an end opposite connectors connecting such lines to interface vessel 230). Double-contained lines 260A-260C are connected to interface vessel 230 through suitable connectors 265A, 265B and 265C, respectively, for a respective secondary line of the double-contained line.

FIG. 3 shows containment vessel 230 having dividers 235 between connectors disposed therein. The dividers define cells to contain the individual connectors for a utility within a cell of interface vessel 230. In one embodiment, in the event of a leak associated with double-contained lines 250A or 250B in their respective cells (e.g., a leak associated with the connection of primary lines), such toxic or flammable utility will leak into the secondary line and the leak noted by a sensor (e.g., sensor 275) on a factory side of interface vessel 230. FIG. 3 also shows a cell associated with containment line 250C that has exhaust port 280. In one embodiment, sensor 285 is connected to exhaust port 280. For certain utilities where it is desired to detect any leak of a connection within a cell at the output side of interface vessel. Sensor 285 is operable to detect such leak.

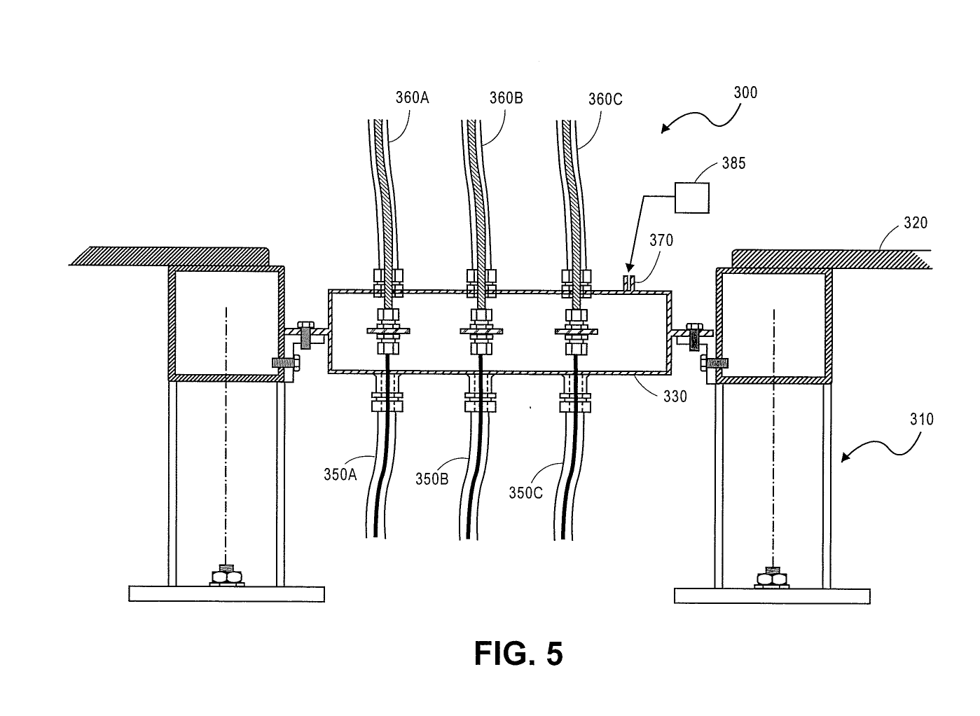

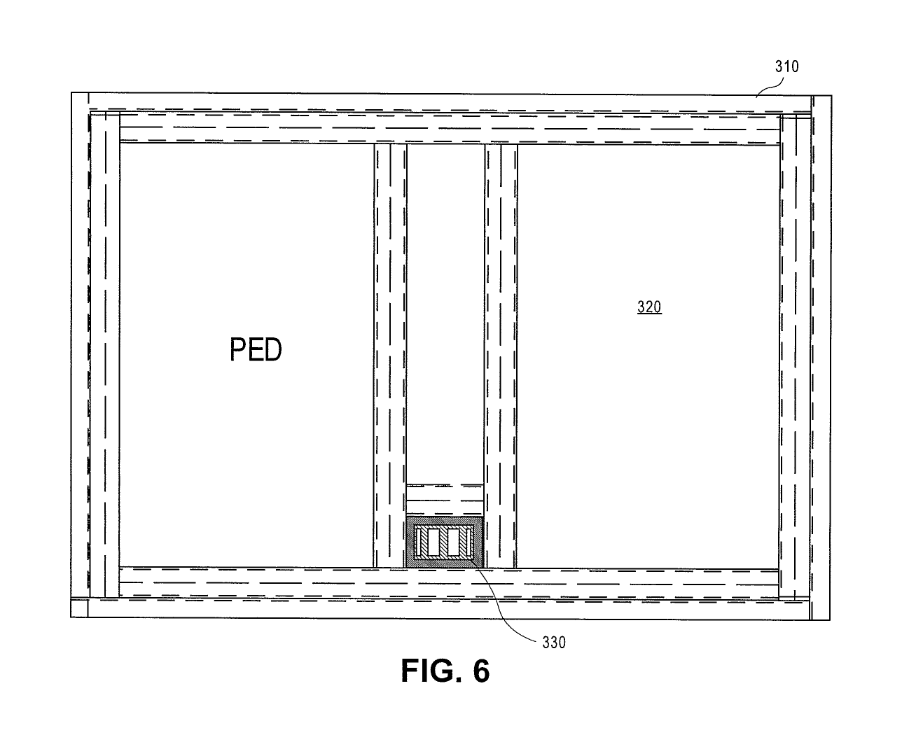

FIG. 5 shows a cross-sectional side view of another embodiment of an assembly of a pedestal including an interface (an interface vessel) disposed therein. FIG. 6 is a top plan view of the pedestal and interface of FIG. 5. Referring to FIG. 5 and FIG. 6, interface of assembly 300 includes interface vessel 330 similar to interface vessel 230 of FIG. 3 and FIG. 4. Interface vessel, in one embodiment, is operable to connect to double-contained lines on opposite sides of the interface vessel. FIG. 5 shows double-contained line 350A, double-contained line 350B and double-contained line 350C connected on an input side to interface vessel 330 through suitable connectors. FIG. 5 also shows double-contained line 360A, double-contained line 360B and double-contained line 360C connected on an output side (tool side) to suitable connectors through interface vessel 330. In the embodiment shown in FIG. 5, interface vessel 330 is not divided into cells for respective ones of primary line connectors for the primary line of the respective double-contained lines. In one embodiment, interface vessel 330 is suitable for utilities of different gases. Interface vessel 330 contains exhaust port 380 on an output side of interface vessel 330. Connected to exhaust port 380 is sensor 385 that, in one embodiment, contains sensors to detect different utility gases (e.g., capable of detecting the presence of one utility gas relative to another). In one embodiment, sensor 385 may be incorporated in a gas box associated with a tool.

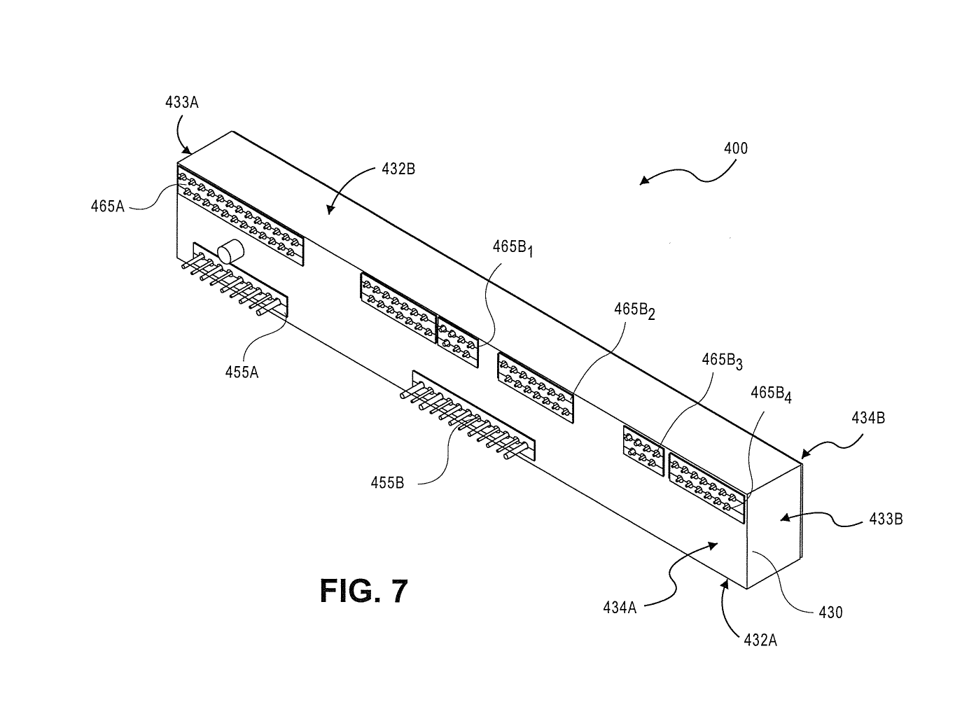

FIG. 7 shows a top side perspective view of another embodiment of an interface vessel operable to be connected to a pedestal. Referring to FIG. 7, interface vessel 430 is defined by opposing sides 432A/432B, 433A/433B, and 434A/434B. In one embodiment, interface vessel is operable to be connected to a pedestal at one of the opposing sides (e.g., 433A/433B). Interface vessel 430, in this embodiment, is operable to interface utilities, specifically input gas sources, to one or more tools. FIG. 7 shows input connectors 455A and input connectors 455B on side 434A. Representatively, input connectors 455A are for hazardous production material (HPM) gases and may be connectors to connect to double-contained lines while input connectors 455B are for inert gases and may not be connectors to connect to double-contained lines. As illustrated in FIG. 7, each of input connectors 455A and input connectors 455B are assemblies of nine input connectors. Interface vessel 430 also includes output connectors 465A, 465B, 465B2, 465B3 and 465B4, in this embodiment, connected to side 434A of the vessel (the same side as input connectors 455A/455B). Output connectors 465A are for HPM gases and may be connected to double-contained lines. FIG. 7 shows an assembly of 25 output connectors 465. Output connectors 465A are connected to input connectors 455A. Since there are more than twice as many output connectors as input connectors, at least some of output connectors 465A are manifolded out of individual ones of input connectors 455A. In one embodiment, each of output connectors 465B, 465B2, 465B3 and 465B4 are for inert gases and are connected to input connectors 455A. As illustrated, the number of output connectors in the assemblies of output connectors 465B, 465B2, 465B3 and 465B4 are significantly greater than input connectors 455B. Accordingly, at least some of output connectors 465B, 465B2, 465B3 and 465B4 are manifolded out of individual ones of input connectors 455B.

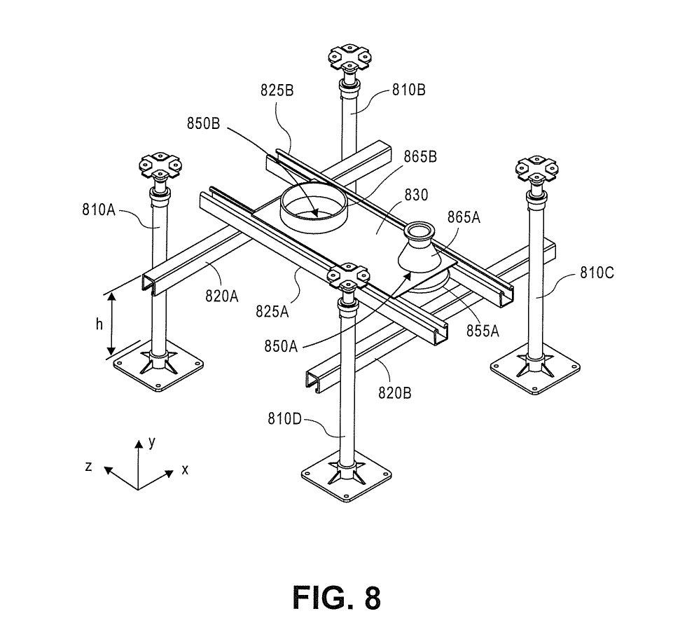

In the above embodiments, a description of a pedestal including an interface plate was described. Generally, heavier tools tend to be positioned on pedestals in semiconductor fabrication facilities. Such facilities generally have a raised metal floor (RMF) that might be built around any such tool pedestals. Lighter tools are often positioned on the RMF and not on a pedestal. Accordingly, in another embodiment, an interface is operable to connect utilities to tools that are to be positioned on a RMF. FIG. 8 shows a top side perspective view of a portion of an RMF having an interface connected thereto. A representative RMF floor consists of an assembly of 24 inch×24 inch (61 centimeters×61 centimeters) supported by legs that are approximately 24 inches (61 centimeters) tall. FIG. 8 specifically shows four legs 510A, 510B, 510C and 510D that are positioned to support a square floor tile (not shown) at each corner. In this embodiment, an interface plate will be connected to legs 510A-510D beneath a floor tile. FIG. 8 shows slotted channel support 520A (a metal material) connected to each of adjacent legs 510A and 510B and slotted channel support 520B connected to each of adjacent legs 510C and 510D. Each of support 520A and support 520B is connected to respective ones of legs 510A/510B and legs 510C/510D at a distance, h, from a floor where h is less than a height or z-dimension of each leg. FIG. 8 also shows slotted channel supports 525A and 525B each extending between support 520A and support 520B and separated by a distance to support opposite sides of an interface plate. Interface plate 530 is disposed on (directly in contact with) supports 525C and 525D. Interface plate 530 may be connected to the supports 525C and 525D by clamps or another mechanism. Assuming legs 510A-510D are spaced to support a 24 inch×24 inch floor tile, in this embodiment, interface plate has an x-dimension and a y-dimension that are each less than 24 inches, thus requiring supports 525C and 525D.

In the embodiment shown in FIG. 8, interface plate 530 of, for example, a metal material, includes opening 550A and opening 550B with input and output connectors connected to opposite sides of interface plate 530 at the openings for a vacuum and an exhaust, respectively. FIG. 8 shows input connector 555A disposed around or in opening 5850A on an underside surface of interface plate 130 (as viewed). Input connector 555A, in this embodiment, is suitable for connection to a hose of a vacuum pump. In one embodiment, such a hose has an inside diameter on the order of two inches (5 centimeters) so input connector has an outside diameter to accommodate such hose. Disposed around or in opening 550A on a top side or output side surface of interface plate 530 is output connector 565A. In one embodiment, an intake vacuum hose into a tool has a smaller diameter (e.g., one inch (2.5 centimeters)) than a hose to input connector 555A (two inches). FIG. 8 shows output connector 565A that is also a reducer (diameter reducer) or connected to a reducer. FIG. 8 also shows output connector 565B disposed around or in opening 550B through interface plate 530 that is a fitting for an exhaust hose from a tool. A similar input connector may be disposed on an underside of interface plate 530.

The description of interface plate 530 is one example of an interface plate that is operable for connection to legs of an RMF. Any of the above embodiments described with reference to connection to a pedestal may alternatively be connected to an RMF (e.g., to legs of an RMF).

### EXAMPLES

Example 1 is apparatus including an interface operable to be connected to a pedestal or a raised floor for an integrated circuit tool, the interface containing a plurality of openings for utility connections on an input side and on an output side of the interface.

In Example 2, the apparatus of Example 1 further includes a plurality of fittings disposed in respective ones of the plurality of openings on the input side and on the output side, the plurality of fittings operable for connection to utility connections.

In Example 3, at least ones of the plurality of fittings in the apparatus of Example 2 are different than others of the plurality of fittings.

In Example 4, the interface in the apparatus of Example 1 is a plate.

In Example 5, the interface in the apparatus of Example 1 is a vessel.

In Example 6, the vessel in the apparatus of Example 3 includes a plurality of cells.

In Example 7, the vessel in the apparatus of Example 5 includes an exhaust port.

In Example 8, the apparatus of Example 7 further includes a sensor coupled to the exhaust port.

In Example 9, the apparatus of Example 1 further includes a tool pedestal including a surface plate operable to support a tool.

Example 10 is an apparatus including an interface operable to be connected to a pedestal or a raised floor and containing a plurality of openings for utility connections on an input side and on an output side of the interface; connectors connected through respective openings in the interface, the connectors operable for connection to a respective utility; and a tool coupled to respective ones of the connectors.

In Example 11, the apparatus of Example 10 further includes a plurality of fittings disposed in respective ones of the plurality of openings on the input side and on the output side, the plurality of fittings operable for connection to utility connections.

In Example 12, the interface in the apparatus of Example 10 is a plate.

In Example 13, the interface in the apparatus of Example 10 is a vessel.

In Example 14, the vessel in the apparatus of Example 13 includes a plurality of cells.

In Example 15, the vessel in the apparatus of Example 13 includes an exhaust port.

In Example 16, the apparatus of Example 10 further includes a pedestal wherein the interface is coupled to the pedestal.

In Example 17, the raised floor in the apparatus of Example 10 includes a plurality of legs that support individual floor tiles, wherein the interface is coupled to adjacent ones of the plurality of legs.

Example 18 is a method including coupling one or more utilities from a source to an input side of an interface coupled to a pedestal or a raised floor; and coupling a tool to the one or more utilities at an output side of the interface.

In Example 19, the interface in the method of Example 18 is a plate.

In Example 20, the interface in the method of Example 18 is a vessel.

In Example 21, the vessel in the method of Example 20 includes a plurality of cells.

In Example 22, at least one of the one or more utilities from the source in the method of Example 20 are coupled to the interface by a double-contained line with a secondary of the double contained line coupled to the exterior of the vessel and a primary of the double-contained line coupled to a connector in the interior of the vessel.

In Example 23, the vessel in the method of Example 20 includes an exhaust port and the method comprises coupling a sensor to the exhaust port.

In Example 24, an integrated circuit tool interface made by the method of any of Examples 18-23.

The above description of illustrated implementations, including what is described in the Abstract, is not intended to be exhaustive or to limit the invention to the precise forms disclosed. While specific implementations of, and examples for, the invention are described herein for illustrative purposes, various equivalent modifications are possible within the scope, as those skilled in the relevant art will recognize.

These modifications may be made to the invention in light of the above detailed description. The terms used in the following claims should not be construed to limit the invention to the specific implementations disclosed in the specification and the claims. Rather, the scope is to be determined entirely by the following claims, which are to be construed in accordance with established doctrines of claim interpretation.

1. An apparatus comprising:
an interface operable to be connected to a pedestal or a raised floor for an integrated circuit tool, the interface containing a plurality of openings for utility connections on an input side and on an output side of the interface.

2. The apparatus of claim 1, further comprising a plurality of fittings disposed in respective ones of the plurality of openings on the input side and on the output side, the plurality of fittings operable for connection to utility connections.

3. The apparatus of claim 2, wherein at least ones of the plurality of fittings are different than others of the plurality of fittings.

4. The apparatus of claim 1, wherein the interface is a plate.

5. The apparatus of claim 1, wherein the interface is a vessel.

6. The apparatus of claim 5, wherein the vessel comprises a plurality of cells.

7. The apparatus of claim 5, wherein the vessel comprises an exhaust port.

8. The apparatus of claim 7, further comprising a sensor coupled to the exhaust port.

9. The apparatus of claim 1, further comprising a tool pedestal including a surface plate operable to support a tool.

10. An apparatus comprising:
an interface operable to be connected to a pedestal or a raised floor and containing a plurality of openings for utility connections on an input side and on an output side of the interface;
connectors connected through respective openings in the interface, the connectors operable for connection to a respective utility; and
a tool coupled to respective ones of the connectors.

11. The apparatus of claim 10, further comprising a plurality of fittings disposed in respective ones of the plurality of openings on the input side and on the output side, the plurality of fittings operable for connection to utility connections.

12. The apparatus of claim 10, wherein the interface is a plate.

13. The apparatus of claim 10, wherein the interface is a vessel.

14. The apparatus of claim 13, wherein the vessel comprises a plurality of cells.

15. The apparatus of claim 13, wherein the vessel comprises an exhaust port.

16. The apparatus of claim 10, further comprising a pedestal wherein the interface is coupled to the pedestal.

17. The apparatus of claim 10, wherein the raised floor comprises a plurality of legs that support individual floor tiles, wherein the interface is coupled to adjacent ones of the plurality of legs.

18. A method comprising:
coupling one or more utilities from a source to an input side of an interface coupled to a pedestal or a raised floor; and
coupling a tool to the one or more utilities at an output side of the interface.

19. The method of claim 18, wherein the interface is a plate.

20. The method of claim 18, wherein the interface is a vessel.

21. The method of claim 20, wherein the vessel comprises a plurality of cells.

22. The method of claim 20, wherein at least one of the one or more utilities from the source are coupled to the interface by a double-contained line with a secondary of the double contained line coupled to the exterior of the vessel and a primary of the double-contained line coupled to a connector in the interior of the vessel.

23. The method of claim 20, wherein the vessel comprises an exhaust port and the method comprises coupling a sensor to the exhaust port.

24. (canceled)
